(19) United States
(12) Patent Application Publication
(10) Pub. No.: US 2009/0001441 A1
(43) Pub. Date: Jan. 1, 2009

(54) Three dimensional quantum dot array

(76) Inventors: Been-Yih Jin, Lake Oswego, OR (US); Brian S. Doyle, Portland, OR (US); Jack T. Kavalieros, Portland, OR (US); Robert S. Chau, Beaverton, OR (US)

Correspondence Address: TROP PRUNER & HU, PC, 1616 S. VOSS ROAD, SUITE 750, HOUSTON, TX, 77057-2631, US

(21) Appl. No.: 11/823,758

(22) Filed: Jun. 28, 2007

(51) Int. Cl. H01L 21/336; H01L 29/788

(52) U.S. Cl. 257/315; 438/257; 257/E29.3; 257/E21.422

(57) ABSTRACT

In one embodiment of the invention, oxidation of silicon in a silicon germanium/silicon lattice may convert a two dimensional array of silicon germanium pillars into a structured three dimensional quantum dot array. The array may be included in, for example, flash memory floating gate, optical detector, or quantum computing device.

### BACKGROUND

A transistor may include a doped well, a source, a drain, and a gate. The gate may include a tunnel dielectric, a quantum dot floating gate, a control gate dielectric, and a control gate. The quantum dots included in the floating gate may vary significantly in size, alignment, and location. For example, the quantum dots may include different maximum breadths or diameters. The dots may be randomly distributed and thus lack a structured pattern or arrangement. Further, the random distribution of dots may result in clustering of dots at or near the gate/tunnel dielectric interface. Even along this interface, the quantum dots may congregate near, for example, a particular transistor terminal such as the source or drain. Thus, semiconductor device designers face difficulties in controlling quantum dot size, alignment, and location or placement of nanometer quantum dots. This complicates the enablement of device scaling into, for example, the nanometer scale.

### BRIEF DESCRIPTION OF THE DRAWINGS

The accompanying drawings, incorporated in and constituting a part of this specification, illustrate one or more implementations consistent with the principles of the invention and, together with the description of the invention, explain such implementations. The drawings are not necessarily to scale, the emphasis instead being placed upon illustrating the principles of the invention. In the drawings:

FIG. 1 is based on a method in one embodiment of the invention.

FIG. 2 is based on a method in one embodiment of the invention.

FIG. 3 is based on a method in one embodiment of the invention.

FIG. 4 is based on a method in one embodiment of the invention.

### DETAILED DESCRIPTION

The following description refers to the accompanying drawings. Among the various drawings the same reference numbers may be used to identify the same or similar elements. While the following description provides a thorough understanding of the various aspects of the claimed invention by setting forth specific details such as particular structures, architectures, interfaces, and techniques, such details are provided for purposes of explanation and should not be viewed as limiting. Moreover, those of skill in the art will, in light of the present disclosure, appreciate that various aspects of the invention claimed may be practiced in other examples or implementations that depart from these specific details. At certain junctures in the following disclosure descriptions of well known devices, circuits, and methods have been omitted to avoid clouding the description of the present invention with unnecessary detail.

In one embodiment of the invention, a preferential oxidation of silicon (Si) in a silicon germanium/silicon (SiGe/Si) superlattice structure may convert a two dimensional array of SiGe superlatice pillars into a structured (i.e., non-random) three dimensional quantum dot array. Thus, in one embodiment of the invention a floating gate in a flash memory may include a structured three dimensional array. This array may foster a flash memory that requires less power to store a multitude of voltage thresholds (i.e., multilevel memory). A method and apparatus concerning such a three dimensional quantum dot array will now be described.

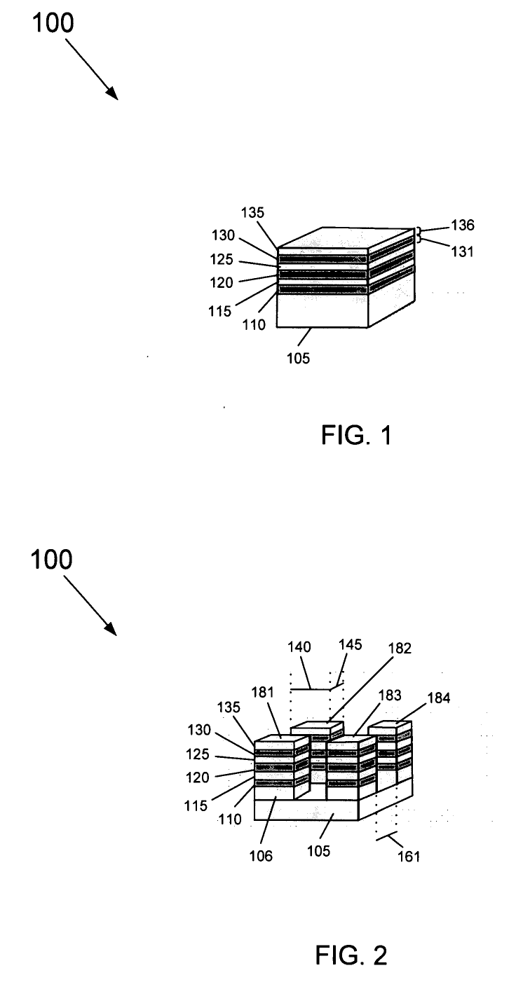

FIG. 1 is based on a method in one embodiment of the invention. A Si₁₋ₓGeₓ/Si superlattice 100 is formed on a Si substrate 105. In one embodiment of the invention, Si₁₋ₓGeₓ layers 110, 120, 130 are separated by Si layers 115, 125, and formed with Si layer 135. Each Si₁₋ₓGeₓ layer and Si layer may include a vertical thickness 131, 136 of about 10 nanometers (nm). Of course, other thicknesses may be used for the Si₁₋ₓGeₓ and/or Si layers. For example, each layer 110, 120, 130, 115, 125, 135 may be thinner than 10 nanometers. Thus, layers 110, 120, 130, 115, 125, 135 form a stack about 60 nm in height. In one embodiment of the invention, x is about 10%-20%. In various embodiments of the invention, superlattice materials other than SiGe/Si may be formed such as InGaAs/GaAs or GaAs/GaAlAs semiconductor supperlattice systems, where substrate 105 may include any suitable material or materials such as germanium, gallium arsenide, indium phosphide, silicon on insulator, or the like. Substrate material selection may take into account lattice matching with the materials used in the superlattice structures (i.e., pillars).

FIG. 2 is based on a method in one embodiment of the invention. The aforementioned stack may be patterned to form multiple superlattice pillars. In one embodiment of the invention, four pillars 181, 182, 183, 184 are patterned but of course fewer or more pillars may be formed. The four pillars 181, 182, 183, 184 of FIG. 2, however, are used to illustrate concepts that concern certain embodiments of the invention. In one embodiment of the invention, each pillar 181, 182, 183, 184 may include a horizontal cross-section of 10 nm (width 140)×10 nm (depth 145). The pillars may be formed on the substrate 105. Layer 106 is an unetched portion of the substrate 105. The interpillar spacing 161 may be based on, for example, traditional lithography techniques, spacer defined pitch, and etching technique. In one embodiment of the invention, the interpillar spacing 161 is about 10 nm. In various embodiments of the invention, interpillar spacing may vary. For example, three sequential pillars may each have a horizontal center axis such that each axis is collinear with the axis of the other two pillars. Each axis may have a center point. A distance between the center point of the first pillar and the center point of the second pillar may be larger or smaller than the distance between the center point of the second pillar and the center point of the third pillar.

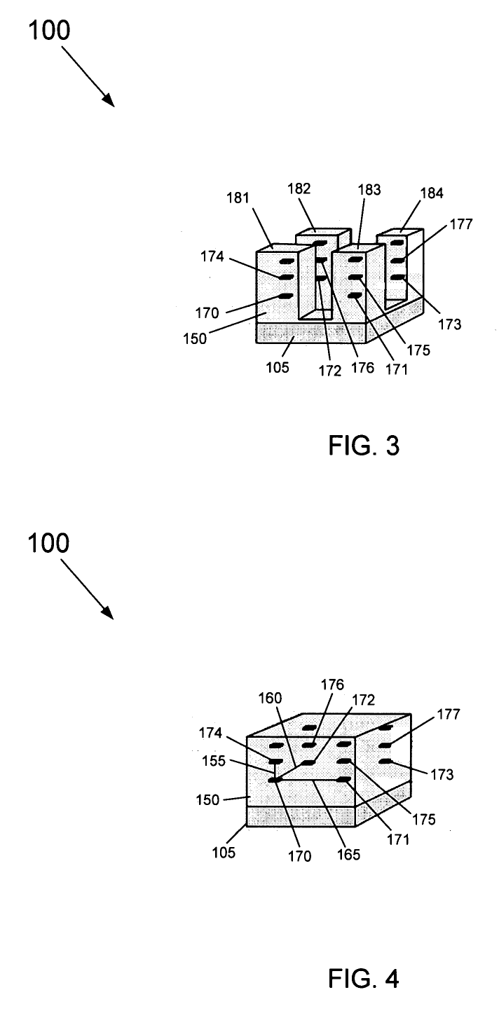

FIG. 3 is based on a method in one embodiment of the invention. The Si₁₋ₓGeₓ/Si superlattice pillars 181, 182, 183, 184 are oxidized to form a three dimensional, self-aligned array of Ge quantum dots 170, 171, 172, 173, 174, 175, 176, 177 located amongst silicon dioxide (SiO₂) 150. In FIG. 4, isolation dielectric (e.g., SiO₂) 150 is formed to fill trenches between the pillars 181, 182, 183, 184. In one embodiment of the invention, the quantum dots 170, 171, 172, 173, 174, 175, 176, 177 include about 5 nm diameters. Of course, in alternative embodiments the dots may be larger or smaller. For example, the quantum dots may be about 5 to 40 nm across. In an embodiment, the quantum dots may be about 3 to 10 nm across. In another embodiment, the quantum dots may be about 5 to 15 nm across. In addition, each dot need not necessarily be the same size. Regarding spacing between dots, dot 170 may be about 20 nm from dot 171. Dot 170 may be about 20 nm from dot 172. Dot 170 may be about 35 nm from dot 174. Of course, the spacing may vary. For example, dot 170 may be about 20 nm from dot 174 in one embodiment of the invention. The twelve quantum dots in FIG. 4 illustrate a self-aligned 2 dot (width)×2 dot (depth)×3 dot (height) structured array.

In various embodiments of the invention, a quantum dot may include a single material or several materials. In one embodiment of the invention, quantum dots may include Germanium. In other embodiments, quantum dots may include boron, aluminum, gallium, indium, thallium, nitrogen, phosphorous, arsenic, antinomy, bismuth, nickel, iron, cobalt, or combinations thereof. For example, boron, arsenic, phosphorous, nickel, iron, and cobalt may be embedded in the quantum dot as a dopant or to create a desired magnetic spin.

In one embodiment of the invention, the quantum dot dimension (e.g., 174) may be based upon a SiGe layer (e.g., 131) thickness, Ge concentration (e.g., Si₁₋ₓGeₓ where x=is about 10%-30%), and the pillar area size (e.g., width 140×depth 145) in the SiGe superlattice pillars. The number of Ge quantum dots and the horizontal plane dot to dot spacing (e.g., 160, 165) may be controlled by the pillar spacing, and vertical dot to dot spacing (e.g., 155) may be controlled by the SiGe/Si superlattice modulation wavelength (i.e., (Si₁₋ₓGeₓ layer thickness)/(Si layer thickness)). In one embodiment of the invention, 400 Å Si_{0.80}Ge_{0.20} epitaxial layers are grown in a Si0.80Ge0.20/Si superlattice on a Si substrate and oxidized at 1000° C. for approximately 800-1,200 seconds.

In one embodiment of the invention, the apparatus 100 of FIG. 4 may be included in a floating gate of a flash memory (not shown), where the SiO2 embedding the Ge quantum dots serves as the inter-dot layer tunnel oxide, and the SiO2 on the top of the quantum dot array serves as the control gate dielectrics. A control gate may be formed above the floating gate. Source and drain regions may be formed in the substrate along with a channel, contacts, and interconnects using traditional fabrication techniques. Various implementations and embodiments of the invention include, for example only, non-volatile memory cells, logic devices, optical detectors, and quantum computing applications (e.g., the Ge quantum dots may be doped in-situ with magnetic dopants such as iron, nickel, and cobalt in the Si₁₋ₓGeₓ layer and form a 3 dimensional spin qbit array for quantum computing).

More specifically, a method for creating a floating gate that includes quantum dots will now be addressed. A transistor may be formed by standard techniques in and on a substrate. The transistor may include a doped well, isolation regions, source, source tip, drain, drain tip, channel, and spacers. The transistor may also include a gate dielectric, a gate electrode, and an interlayer dielectric. The gate dielectric and gate electrode may be referred to as a gate stack or a gate structure. In an embodiment of the invention, a gate dielectric may include silicon dioxide and a gate electrode may include polysilicon.

A gate dielectric and gate electrode may be deposited on the quantum dot array and patterned to form gatelines (wordlines). The gate dielectric and gate electrode may be patterned by any suitable technique, such as lithography and a selective etch process.

A separate tunnel dielectric may be formed in the form of silicon on tunnel oxide substrate. The tunnel dielectric may be formed by any suitable technique, such as chemical vapor deposition (CVD), physical vapor deposition (PVD), atomic layer deposition (ALD), or the like. In some embodiments, in forming the tunnel dielectric, a deposited dielectric material may be formed over a silicon carrier substrate, whereupon a thin Si layer is formed on top of the tunnel oxide by a wafer bonding technique such as a Si implanted smart cut technique. The SiGe/Si superlattice is grown on top of the Si on tunnel oxide substrate, follow by the oxidation process to form the Ge quantum dot floating gate array. The tunnel dielectric may include any material or materials as discussed above. In general, the tunnel dielectric may be referred to as a dielectric layer, a dielectric material, or a dielectric. In various embodiments, the tunnel dielectric may include silicon dioxide, hafnium silicon oxide, hafnium oxide, lanthanum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, lead zinc niobate, or any combination thereof.

The quantum dot floating gate, described above, may be formed over a Si substrate or over the Si on tunnel oxide substrate. Quantum dot floating gates may be formed using various suitable techniques, such as those addressed above. In an embodiment, a quantum dot floating gate may be formed by growing superlattice using a CVD or a molecular beam epitaxial process.

Forming a quantum dot floating gate in a replacement gate process may offer the advantage that the subsequent process flow does not require a high temperature step after the formation of the quantum dot floating gate. In an embodiment, all of the high temperature process steps that may be required in forming the transistor, such as source and drain activation anneal, may already be complete. A high temperature step, such as an anneal, after forming the quantum dot floating gate may degrade the quantum dot quality and deform the quantum dots physical dimensions.

A separate control gate dielectric such as high dielectric constant HfO₂, ZrO₂, SrTiO₃, BaTiO₃, may be formed over the quantum dot floating gate array. A control gate dielectric may be formed by any suitable technique, such as CVD, PVD, ALD, or the like. In an embodiment, a control gate dielectric may be formed in a conformal manner over quantum dot floating gate, such that control gate dielectric conforms to the quantum dot floating gate and leaves the quantum dot floating gate relatively unchanged. In another embodiment, a control gate dielectric may be formed in a conformal manner using ALD. In some embodiments, in forming the control gate dielectric, a dielectric material may also be formed over an interlayer dielectric or previously deposited materials. In such embodiments, the dielectric material over interlayer dielectric or previously deposited materials may be subsequently removed by any suitable technique. The control gate dielectric may be generally referred to as a dielectric layer or a dielectric.

A control gate may be formed over the control gate dielectric. The control gate may be formed by any suitable technique, such as CVD, PVD, ALD, electroplating or the like. In some embodiments, in forming the control gate, the deposited material may also be formed over the interlayer dielectric or previously deposited materials. In such embodiments, the control gate material over the interlayer dielectric or previously deposited materials may be removed by any suitable technique such as an etch step or CMP. Generally, the control gate may be referred to as a conductor or a conductive layer or a conductive plug.

The interlayer dielectric and any materials previously deposited over the interlayer dielectric may be removed. The materials may be removed by any suitable technique, such as CMP, wet etch, dry etch, or the like. Further, spacers and silicide regions may be formed by any suitable technique. The spacers may include any suitable materials, such as a nitride or an oxide. The silicide regions may also include any suitable material. In an embodiment, the silicide regions may include a metal. In another embodiment, the silicide regions may include nickel.

An interlayer dielectric may be deposited and contacts may be formed. The interlayer dielectric may be formed by any suitable technique and may include any suitable insulative material or materials. In an embodiment, forming the interlayer dielectric may include a deposition step and a CMP step. The contacts may also be formed by any suitable technique, such as lithography, etch, deposition, and planar techniques. The contacts may include any suitable conductive material. In some embodiments, the contacts may include a metal. The contacts may provide electrical contact to the source, drain, and control gate.

Reference throughout this specification to “one embodiment” or “an embodiment” means that a particular feature, structure, material, or characteristic described in connection with the embodiment is included in at least one embodiment of the invention. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments.

While the present invention has been described with respect to a limited number of embodiments, those skilled in the art will appreciate numerous modifications and variations therefrom. It is intended that the appended claims cover all such modifications and variations as fall within the true spirit and scope of this present invention.

What is claimed is:

1. An method comprising:
receiving a substrate;
forming a lower layer above the substrate, the lower layer including Ge and Si;
forming an upper layer above the lower layer, the upper layer including Ge and Si;
forming an intermediate layer between the lower layer and the upper layer, the intermediate layer including Si;
patterning the lower layer, intermediate layer, and upper layer to form a first pillar, a second pillar, a third pillar, and a fourth pillar; and
oxidizing the first pillar, the second pillar, the third pillar, and the fourth pillar to form a plurality of Ge quantum dots in a structured three dimensional array.

2. The method of claim 1, further comprising forming a floating gate that includes the three dimensional array.

3. The method of claim 2, further comprising forming an insulative material between the first pillar, the second pillar, the third pillar, and the fourth pillar.

4. The method of claim 1, further comprising forming the three dimensional array to include a first plane formed below a second plane, the first plane including a first Ge quantum dot, a Ge second quantum dot, a third Ge quantum dot, and a Ge fourth quantum dot collectively formed in a coplanar, non-collinear pattern, and the second plane including a fifth Ge quantum dot, a sixth Ge quantum dot, a seventh Ge quantum dot, and an eighth Ge quantum dot collectively formed in a coplanar, non-collinear pattern.

5. The method of claim 1, further comprising forming each of the plurality of Ge quantum dots to include a maximum diameter less than or equal to 5 nm.

6. The method of claim 1, further comprising determining the size of each of the plurality of Ge quantum dots based on the vertical thickness of the lower layer, the vertical thickness of the upper layer, the Ge concentration of the lower layer, and the Ge concentration of the upper layer.

7. The method of claim 4, further comprising determining a first distance between the first Ge quantum dot and the second Ge quantum dot based on a second distance between the first pillar and the second pillar.

8. The method of claim 7, further comprising determining the first distance based on a lattice modulation wavelength for the lower layer and the intermediate layer.

9. The method of claim 4, further comprising determining a first height between the fifth quantum dot and the substrate based on a vertical thickness of each of the lower layer, the upper layer, and the intermediate layer.

10. The method of claim 1, further comprising including the plurality of Ge quantum dots in at least one of a memory device, a logic device, and an optical detector device.

11. The method of claim 2, further comprising including the floating gate in a memory device to store data based on three or more voltage thresholds.

12. An apparatus comprising:
a substrate; and
a three dimensional array that includes a first plane formed below a second plane, the first plane including a first quantum dot, a second quantum dot, a third quantum dot, and a fourth quantum dot collectively formed in a coplanar, non-collinear pattern, and the second plane including a fifth quantum dot, a sixth quantum dot, a seventh quantum dot, and an eighth quantum dot collectively formed in a coplanar, non-collinear pattern.

13. The apparatus of claim 12, further comprising a floating gate that includes the three dimensional array, the floating gate to store data based on three or more voltage thresholds.

14. The apparatus of claim 12, wherein the plurality of quantum dots each include Ge and each include a maximum diameter less than or equal to 5 nm.

15. The apparatus of claim 12, wherein a first height between the fifth quantum dot and the substrate is at least 20 nm and a first distance between the fifth quantum dot and the sixth quantum dot is at least 15 nm, wherein no additional quantum dot is formed collinearly with the fifth quantum dot and sixth quantum and in between the fifth quantum dot and sixth quantum dot.
